(19) United States
(12) Patent Application Publication
(10) Pub. No.: US 2019/0072796 A1
(43) Pub. Date: Mar. 7, 2019

(54) ORGANIC THIN FILM TRANSISTOR HAVING PERPENDICULAR CHANNELS IN PIXEL STRUCTURE AND METHOD FOR MANUFACTURING SAME

(71) Applicant: Shenzhen China Star Optoelectronics Technology Co. Ltd., Shenzhen (CN)

(72) Inventor: Ziran LI, Shenzhen (CN)

(73) Assignee: SHENZHEN CHINA STAR OPTOELECTRONICS TECHNOLOGY CO., LTD., Shenzhen (CN)

(21) Appl. No.: 15/578,720

(22) PCT Filed: Nov. 8, 2017
(86) PCT No.: PCT/CN2017/109829

§ 371 Date: Dec. 1, 2017

(30) Foreign Application Priority Data
Sep. 1, 2017 (CN) 201710779318.8

(51) Int. Cl. G02F 1/1368; G02F 1/1343

(52) U.S. Cl. CPC G02F 1/1368; G02F 1/134363; H01L 29/78642; G02F 2202/103; G02F 2201/40

(57) ABSTRACT

An organic thin film transistor having perpendicular channels in a pixel structure is provided with a first electrode layer distributing on a substrate, and the first electrode layer having a source electrode layer; and a second electrode layer disposed on a top portion the substrate, and the second electrode layer having a pixel electrode layer and a drain electrode layer. An insulating layer is disposed between the first electrode layer and the substrate. A plurality of channels which are perpendicular to the insulating layer are distributing on the pixel electrode layer and the insulating layer. The channels divide the pixel electrode layer into a plurality of dimensional pixel electrodes separating from each other. An active layer is deposited on the drain electrode layer and the source electrode layer. A method for manufacturing the organic thin film transistor having the perpendicular channels in the pixel structure is also provided.

### CROSS-REFERENCE TO RELATED APPLICATIONS

This is the U.S. National Stage of International Patent Application No. PCT/CN2017/109829, filed Nov. 8, 2017, which in turn claims the benefit of Chinese Patent Application No. 201710779318.8, filed Sep. 1, 2017.

### FIELD OF INVENTION

The present invention relates to display technology, and specifically to an organic thin film transistor having perpendicular channels in a pixel structure and a method for manufacturing same.

### BACKGROUND OF INVENTION

With development of display technologies, flat panel display devices, such as liquid crystal displays (LCDs), are widely used in mobile phones, televisions, personal digital assistants, digital cameras, laptops, desktop computers because of their advantages of high image quality, low power consumption, thin body, and wide application range. The LCD has become a mainstream in display devices.

An organic light-emitting diode (OLED) display is known as an organic electroluminescent display, and is a new type of a flat panel display device. Since the OLED display has advantages of self-luminous property, low driving voltage, high luminous efficiency, short response time, high definition and contrast, approximate 180 degrees viewing angle, wide operating temperature range, flexible display, and large area full color display, it is recognized by the industry as the most promising display device.

At present, an in-plane switching (IPS) technology in a liquid crystal display (LCD) panel technology is commonly known as a “Super TFT.” Semiconductor channels of a TFT device mostly adopt a two-dimensional planar structure, and the channels have longer lengths, thereby the on/off ratio is limited in the TFT device. Meanwhile, the size of the TFT device is larger and the aperture ratio is reduced. The IPS mode has the highest driving voltage, and large power consumption.

### SUMMARY OF INVENTION

An object of the present invention is to provide an organic thin film transistor having perpendicular channels in a pixel structure. The thin film transistor (TFT) device has a plurality of channels with a perpendicular structure so as to reduce a length of each channel to increase on/off ratio of the TFT device, reduce the size of the TFT device, and improve the aperture ratio. An in-plane switching (IPS) pixel electrode is formed into a dimensional pixel electrode to reduce a driving voltage and increase a transmittance.

To achieve the above objects, a technical solution is to provide a thin film transistor having perpendicular channels in a pixel structure, comprising a first electrode layer distributed on an upper surface of a substrate, wherein the first electrode layer comprises a common electrode layer and a source electrode layer; and a second electrode layer disposed on a top portion of the upper surface of the substrate, wherein the second electrode layer comprises a pixel electrode layer and a drain electrode layer; wherein an insulating layer is disposed between the first electrode layer and the substrate; a plurality of channels that are perpendicular to the insulating layer and distributed on the pixel electrode layer and a top portion of the insulating layer, the channels configured to divide the pixel electrode layer into a plurality of dimensional pixel electrodes isolated from each other; the pixel electrode layer connects with the drain electrode layer of the organic thin film transistor, an active layer is disposed on the drain electrode layer and the source electrode layer; and a gate electrode layer and a gate insulating layer between the active layer and the gate electrode layer are respectively disposed on the active layer.

In one preferred embodiment of the present invention, each of the drain electrode layer and the source electrode layer is a single layer metal or a multilayer metal.

In one preferred embodiment of the present invention, each of the drain electrode layer and the source electrode layer has a thickness ranging from 100 nm to 400 nm.

In one preferred embodiment of the present invention, a semiconductor material of the active layer is indium gallium zinc oxide or amorphous silicon.

In one preferred embodiment of the present invention, the insulating layer comprises a first insulating layer and a second insulating layer, the second insulating layer is disposed on the first insulating layer, the channels passes through the second insulating layer and a top portion of the first insulating layer.

In one preferred embodiment of the present invention, the first insulating layer is a photoresist insulating layer, and the photoresist insulating layer is a polyfluoroalkoxy (PFA) layer.

In one preferred embodiment of the present invention, the PFA layer has a thickness ranging from 1500 nm to 5000 nm.

In one preferred embodiment of the present invention, a perpendicular distance from a surface of the dimensional pixel electrode to a bottom surface of one of the channels is ranging from 1000 nm to 4000 nm.

Another object of the present invention is to provide a method for manufacturing the abovementioned organic thin film transistor having the perpendicular channels in the pixel structure.

To achieve above object, a technical solution is to provide a method for manufacturing the abovementioned organic thin film transistor having the perpendicular channels in the pixel structure, comprising steps of:

(S1) depositing a first electrode layer on a substrate, and patterning the first electrode layer; (S2) sequentially depositing an insulating layer and a second electrode layer on the substrate, and patterning the insulating layer and the second electrode layer; (S3) sequentially depositing and patterning an active layer, a gate insulating layer, and a gate electrode layer on the substrate and the source electrode layer; (S4) forming a plurality of channels perpendicular to the insulating layer and a dimensional pixel electrode on the pixel electrode layer and a top portion of the insulating layer.

In one preferred embodiment of the present invention, the step (S2) comprises sequentially depositing and patterning a first insulating layer and a second insulating layer on the substrate; and the step (S4) comprises defining a dimensional pixel electrode area, wet-etching for patterning the pixel electrode layer, and dry-etching the second insulating layer and a top portion of the first insulating layer after the first insulating layer is exposed, to form the channels and the dimensional pixel electrode.

In the organic thin film transistor having the perpendicular channels in the pixel structure and the method for manufacturing the same according to the present invention, advantages are that the thin film transistor (TFT) device has a plurality of channels with a perpendicular structure so as to reduce a length of each channel to increase on/off ratio of the TFT device, reduce the size of the TFT device, and improve the aperture ratio. An in-plane switching (IPS) pixel electrode is formed by a metallic material and applicable to a high resolution panel. The IPS pixel electrode is formed into a dimensional pixel electrode by etching the insulating layer, thereby not only to reduce a driving voltage, but also to increase a transmittance.

### BRIEF DESCRIPTION OF DRAWINGS

The description of the following embodiments is used for further explaining the present invention by referring to the accompany drawings.

FIG. 1 is a top view of an organic thin film transistor having a perpendicular channel in a pixel structure.

FIG. 2 is a cross-sectional view of an organic thin film transistor having a perpendicular channel in a pixel structure.

FIG. 3 is a flow chart of a method for manufacturing an organic thin film transistor having a perpendicular channel in a pixel structure.

In above figures:

| | |
|---|---|
| 1: substrate; | 21: common electrode layer; |
| 22: source electrode layer; | 211: common electrode; |
| 31: first insulating layer; | 32: second insulating layer; |
| 41: pixel electrode layer; | 42: drain electrode layer; |
| 411: dimensional pixel electrode; | 6: channel; |
| 51: active layer; | 52: gate insulating layer; |
| 53: gate electrode layer | |

### DETAILED DESCRIPTION OF PREFERRED EMBODIMENTS

The description of the following embodiments is used for exemplifying the specific embodiments of the present invention by referring to the accompany drawings. Furthermore, directional terms described by the present invention, such as upper, lower, front, back, left, right, top, bottom, etc., are only directions by referring to the accompanying drawings, and thus the directional terms are used to describe and understand the present invention, but the present invention is not limited thereto.

### Embodiments

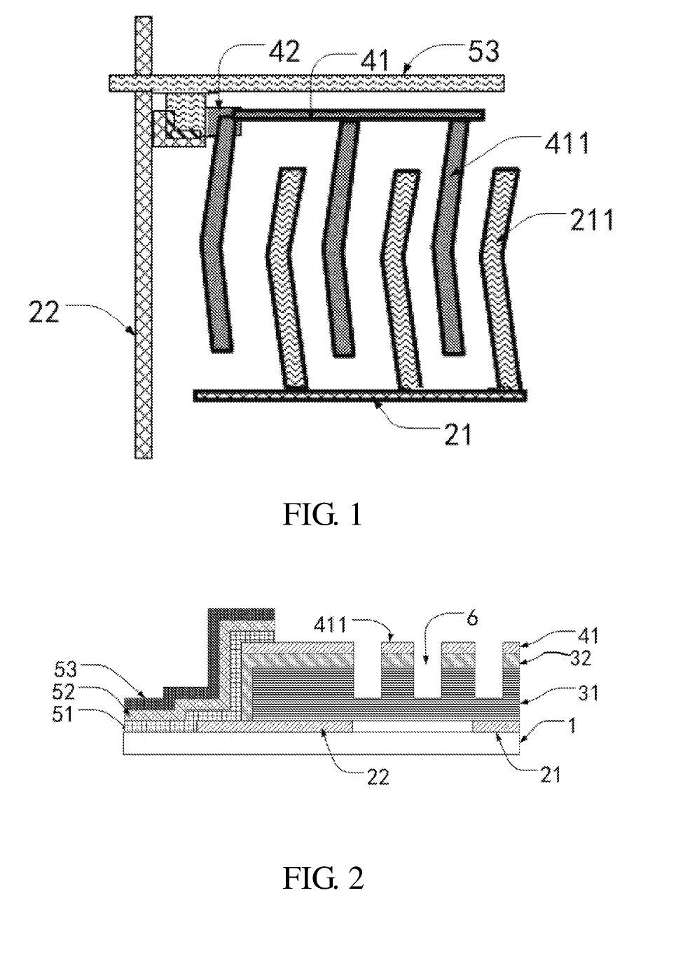

As shown in FIG. 1 and FIG. 2, an organic thin film transistor having a perpendicular channel in a pixel structure comprises a first electrode layer (a common electrode layer 21 and a source electrode layer 22), a second electrode layer (a pixel electrode layer 41 and a drain electrode layer 42), an insulating layer, an active layer 51, a gate insulating layer 52, and a gate electrode layer 53.

In this embodiment, the first electrode layer is distributed on a substrate 1. The first electrode layer comprises a common electrode area and a source electrode area. The common electrode layer 21 is distributed on the common electrode area, and the source electrode layer is distributed on the source electrode layer 22. After patterning, the common electrode layer 21 is divided into a plurality of common electrodes 211 separating from each other. The source electrode layer 22 forms a source electrode after patterning, and the source electrode connects with the common electrode layer 21 through common electrode lines.

In this embodiment, the insulating layer is distributed between the first electrode layer and the substrate 1. The insulating layer comprises a first insulating layer 31, a second insulating layer 32. The first insulating layer 31 is disposed on the substrate 1. The second insulating layer 32 is disposed on the first insulating layer 31. In which, the first insulating layer 31 is a transparent photoresist layer, and the photoresist layer is a polyfluoroalkoxy (PFA) layer. The PFA layer has a thickness ranging from 1500 nm to 5000 nm. The thickness of the PFA layer can be modified according to actual requirements, but it cannot be too thick. The too thick PFA layer will cause the TFT device to have an excessive height which affects performance of the product. It is also not preferred to use a too thin PFA layer because a plurality of perpendicular channels 6 cannot be configured in the thin PFA layer, or the perpendicular channels 6 cannot fulfill performance requirements.

In this embodiment, the second electrode layer is disposed on the second insulating layer 32. The second electrode layer comprises a pixel electrode area and a drain area. A pixel electrode layer 41 is distributed on the pixel electrode area, and a drain electrode layer 42 is distributed on the drain electrode area.

In this embodiment, patterning the pixel electrode layer 41 and the second insulating layer 32 to form channels 6 perpendicular to the second insulating layer 32. The channels 6 pass through the pixel electrode layer 41 and extend to a middle or lower portion of the second insulating layer 32. The channels 6 are configured to divide the pixel electrode layer 41 into a plurality of dimensional pixel electrodes 411 isolated from each other. The height of the dimensional pixel electrode 411 is a perpendicular distance from a surface of the dimensional pixel electrode to a bottom surface of one of the channels 6, and ranges from 1000 nm to 4000 nm. The height of the dimensional pixel electrode 411 is configured according to the height of the insulating layer.

In this embodiment, the active layer 51 is deposited on the drain electrode layer 42 and the source electrode layer 22. The gate electrode layer 53 and the gate insulating layer 52 between the active layer 51 and the gate electrode layer 53 are disposed on the active layer 51.

In this embodiment, the drain electrode layer 42 and the source electrode layer 22 are single layer metals or multilayer metals. Each of the drain electrode layer 42 and the source electrode layer 22 has a thickness ranging from 100 nm to 400 nm. The thicker the thickness is, the higher the height of the channels 6 is. The higher the height of the channels 6 is, the higher the height of the TFT device is, and product performance is affected. In one preferred embodiment of the present invention, a semiconductor material of the active layer 51 is indium gallium zinc oxide or amorphous silicon.

To achieve the abovementioned organic thin film transistor having perpendicular channels 6 in the pixel structure, a method for manufacturing the same comprises steps as described below.

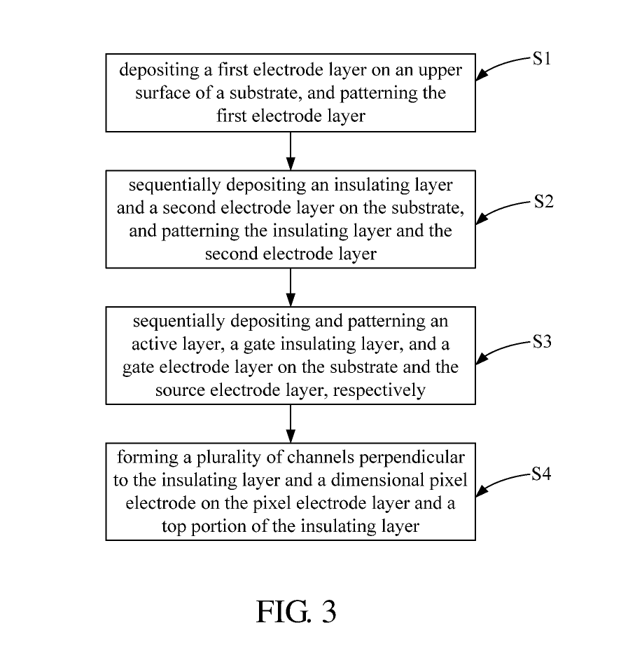

As shown in FIG. 3, a method for manufacturing the organic thin film transistor having the perpendicular channels in the pixel structure comprises steps as following:

Step (S1): depositing a first electrode layer on a substrate 1, and patterning the first electrode layer. In the step (S1), first, the first electrode layer is divided into a common electrode area and a source electrode area. A common electrode layer 21 is deposited on the common electrode area, and a source electrode layer 22 is deposited on the source electrode area, and the common electrode layer 21 and the source electrode layer 22 are patterned, respectively. For example, the common electrode layer 21 forms a plurality of common electrodes 211 after patterning.

Step (S2): sequentially depositing an insulating layer and a second electrode layer on the substrate 1, and patterning the insulating layer and the second electrode layer. In the step (S2), firstly, a first insulating layer 31 is deposited on the substrate 1, and the first insulating layer 31 is patterned. Next, a second insulating layer 32 is deposited on the first insulating layer 31, and the second insulating layer 32 is patterned. Finally, a second electrode layer is deposited on the second insulating layer 32. When depositing the second electrode layer, a drain electrode area and a pixel electrode area are divided, and a drain electrode layer 42 and a pixel electrode 41 are deposited on the drain electrode area and the pixel electrode area, respectively, and then the drain electrode layer 42 and the pixel electrode layer 41 are patterned.

Step (S3): sequentially depositing and patterning an active layer 51, a gate insulating layer 52, and a gate electrode layer 53 on the substrate and the source electrode layer 22, respectively. The active layer 51 extends from a surface of the substrate 1 upward the first electrode layer. The gate insulating layer 52 distributes on the active layer 51, and the gate electrode layer 53 distributes on the gate insulating layer 52.

Step (S4): forming a channel 6 perpendicular to the insulating layer and a dimensional pixel electrode 411 on the pixel electrode layer 41 and a top portion of the insulating layer. The step (S4) comprises defining a dimensional pixel electrode 411 area, wet-etching for patterning the pixel electrode layer 41, and dry-etching the second insulating layer 32 and a top portion of the first insulating layer 31 after the first insulating layer is exposed, so as to form the channels 6 and the dimensional pixel electrode 411. In this embodiment, the dimensional pixel electrode 411 and the common electrodes 211 are staggered.

The foregoing descriptions are merely referred embodiments of the present invention, and are not intended to limit the present invention. Any modifications, equivalent replacements, and improvements made within the spirit and principle of the present invention should be included in the protection scope of the present invention.

1. An organic thin film transistor having perpendicular channels in a pixel structure, comprising:
a first electrode layer distributed on a substrate, wherein the first electrode layer comprises a common electrode layer and a source electrode layer; and
a second electrode layer disposed on a top portion of the substrate, wherein the second electrode layer comprises a pixel electrode layer and a drain electrode layer;
wherein an insulating layer is disposed between the first electrode layer and the substrate;
a plurality of channels that are perpendicular to the insulating layer and distributed on the pixel electrode layer and a top portion of the insulating layer, the channels configured to divide the pixel electrode layer into a plurality of dimensional pixel electrodes isolated from each other;
the pixel electrode layer connects with the drain electrode layer of the organic thin film transistor, an active layer is disposed on the drain electrode layer and the source electrode layer; and
a gate electrode layer and a gate insulating layer between the active layer and the gate electrode layer are respectively disposed on the active layer.

2. The organic thin film transistor having perpendicular channels in a pixel structure according to claim 1, wherein each of the drain electrode layer and the source electrode layer is a single layer metal or a multilayer metal.

3. The organic thin film transistor having perpendicular channels in a pixel structure according to claim 1, wherein each of the drain electrode layer and the source electrode layer has a thickness ranging from 100 nm to 400 nm.

4. The organic thin film transistor having perpendicular channels in a pixel structure according to claim 1, wherein a semiconductor material of the active layer is indium gallium zinc oxide or amorphous silicon.

5. The organic thin film transistor having perpendicular channels in a pixel structure according to claim 1, wherein the insulating layer comprises a first insulating layer and a second insulating layer, the second insulating layer is disposed on the first insulating layer, the channels passes through the second insulating layer and a top portion of the first insulating layer.

6. The organic thin film transistor having perpendicular channels in a pixel structure according to claim 5, wherein the first insulating layer is a photoresist insulating layer, and the photoresist insulating layer is a polyfluoroalkoxy (PFA) layer.

7. The organic thin film transistor having perpendicular channels in a pixel structure according to claim 6, wherein the PFA layer has a thickness ranging from 1500 nm to 5000 nm.

8. The organic thin film transistor having perpendicular channels in a pixel structure according to claim 1, wherein a perpendicular distance from a surface of the dimensional pixel electrode to a bottom surface of one of the channels is ranging from 1000 nm to 4000 nm.

9. A method for manufacturing the organic thin film transistor having perpendicular channels in a pixel structure according to any of claims 1-9, comprising steps of:
(S1) depositing a first electrode layer on a substrate, and patterning the first electrode layer;
(S2) sequentially depositing an insulating layer and a second electrode layer on the substrate, and patterning the insulating layer and the second electrode layer;
(S3) sequentially depositing and patterning an active layer, a gate insulating layer, and a gate electrode layer on the substrate and the source electrode layer; and
(S4) forming a plurality of channels perpendicular to the insulating layer and a dimensional pixel electrode on the pixel electrode layer and a top portion of the insulating layer.

10. The method for manufacturing the organic thin film transistor having perpendicular channels in a pixel structure according to claim 9, wherein the step (S2) comprises sequentially depositing and patterning a first insulating layer and a second insulating layer on the substrate; and the step (S4) comprises defining a dimensional pixel electrode area, wet-etching for patterning the pixel electrode layer, and dry-etching the second insulating layer and a top portion of the first insulating layer after the first insulating layer is exposed, to form the channels and the dimensional pixel electrode.
